(19) United States
(12) Patent Application Publication
(10) Pub. No.: US 2018/0148274 A1
(43) Pub. Date: May 31, 2018

(54) SHEET MEMBER INSPECTION METHOD AND SHEET MEMBER CONVEYING APPARATUS

(71) Applicant: TOYOTA JIDOSHA KABUSHIKI KAISHA, Toyota-shi (JP)

(72) Inventor: Takahiko NAKANO, Seto-shi (JP)

(73) Assignee: TOYOTA JIDOSHA KABUSHIKI KAISHA, Toyota-shi (JP)

(21) Appl. No.: 15/821,127

(22) Filed: Nov. 22, 2017

(30) Foreign Application Priority Data
Nov. 30, 2016 (JP) 2016-232867

(51) Int. Cl. B65G 49/06; B65H 5/14; B65H 29/60; G01N 21/89; G01N 21/952

(52) U.S. Cl. CPC B65G 49/067; B65H 5/14; H01L 21/67706; G01N 21/8914; G01N 21/952; B65H 29/60

(57) ABSTRACT

In a sheet member inspection method for a sheet member conveying apparatus configured to convey a sheet member with a tension, the sheet member conveying apparatus includes: a first support roller placed on an upstream side in a conveying direction of the sheet member and configured to support conveyance of the sheet member; a second support roller placed on a downstream side relative to the first support roller in the conveying direction and configured to support the conveyance of the sheet member; and a magnetic-force detection sensor placed on the downstream side relative to the first support roller in the conveying direction. The sheet member inspection method includes: applying a magnetic force to the sheet member by the first support roller; and inspecting, by the magnetic-force detection sensor, whether a magnetic object exists in the sheet member to which the magnetic force is applied by the first support roller.

### INCORPORATION BY REFERENCE

The disclosure of Japanese Patent Application No. 2016-232867 filed on Nov. 30, 2016 including the specification, drawings and abstract is incorporated herein by reference in its entirety.

### BACKGROUND

### 1. Technical Field

The present disclosure relates to a sheet member inspection method and a sheet member conveying apparatus.

### 2. Description of Related Art

In terms of a manufacturing process of an electrode sheet as a power generation element constituting a secondary battery, a method for detecting an object (a foreign matter) mixed in an electrode sheet or a member constituting the electrode sheet is disclosed in Japanese Unexamined Patent Application Publication No. 2012-138245 (JP 2012-138245 A). In the object (foreign matter) detection method disclosed in JP 2012-138245 A, a magnet and a magnetic-force detection sensor are provided in a conveyance path for a separator, for example, so that an object (a foreign matter) can be detected such that the object (the foreign matter) magnetized by the magnet is detected by the magnetic-force detection sensor.

### SUMMARY

The configuration employed in the object (foreign matter) detection method has such a possibility that, in a case where a position of a sheet member as the power generation element is too far from a position of the magnet, the object (the foreign matter) cannot be magnetized. Further, when the magnet is brought too close to the sheet member, the magnet makes contact with the sheet member, which might damage the sheet member.

The present disclosure provides a sheet member inspection method and a sheet member conveying apparatus, each of which is able to surely magnetize an object mixed in a sheet member, without damaging the sheet member.

The sheet member inspection method for the sheet member conveying apparatus is a sheet member inspection method for conveying a sheet member with a tension so as to detect a magnetic object mixed in the sheet member, and the sheet member conveying apparatus has the following configuration.

That is, the sheet member conveying apparatus includes: a first support roller placed on an upstream side in a conveying direction of the sheet member and configured to support conveyance of the sheet member; a second support roller placed on a downstream side relative to the first support roller in the conveying direction and configured to support the conveyance of the sheet member; and a magnetic-force detection sensor placed on the downstream side relative to the first support roller in the conveying direction and configured to detect a magnetic force.

The first support roller is magnetized, and the sheet member inspection method includes: applying a magnetic force to the sheet member by the first support roller; and inspecting, by the magnetic-force detection sensor, whether or not the object that is magnetized exists in the sheet member to which the magnetic force is applied by the first support roller.

The sheet member conveying apparatus is a sheet member conveying apparatus configured to convey a sheet member with a tension so as to detect a magnetic object mixed in the sheet member, and has the following configuration.

That is, the sheet member conveying apparatus includes: a first support roller placed on an upstream side in a conveying direction of the sheet member and configured to support conveyance of the sheet member; a second support roller placed on a downstream side relative to the first support roller in the conveying direction and configured to support the conveyance of the sheet member; and a magnetic-force detection sensor placed on the downstream side relative to the first support roller in the conveying direction and configured to detect a magnetic force.

The first support roller is magnetized, and in a case where the object is mixed in the sheet member, the object is magnetized by the first support roller, and the object thus magnetized is detected by the magnetic-force detection sensor.

According to the sheet member inspection method and the sheet member conveying apparatus, the conveyance of the sheet member is supported by the first support roller that is magnetized. As a result, in a case where the object is mixed in the sheet member, the object is surely magnetized because the sheet member is conveyed in a state where the sheet member makes contact with the first support roller. Hereby, the magnetic-force detection sensor can surely detect the magnetized object from the sheet member.

According to the sheet member inspection method and the sheet member conveying apparatus, it is possible to provide a sheet member inspection method and a sheet member conveying apparatus, each of which is able to surely magnetize an object mixed in a sheet member, without damaging the sheet member.

### BRIEF DESCRIPTION OF THE DRAWINGS

Features, advantages, and technical and industrial significance of exemplary embodiments of the disclosure will be described below with reference to the accompanying drawings, in which like numerals denote like elements, and wherein:

FIG. 1 is a view illustrating a configuration of a single cell;

FIG. 2 is a sectional view of the single cell;

FIG. 3 is a schematic perspective view of an electrode sheet;

FIG. 4 is a schematic perspective view illustrating a schematic configuration of a sheet member conveying apparatus of Embodiment 1;

FIG. 5 is a schematic side view illustrating a schematic configuration of the sheet member conveying apparatus of Embodiment 1;

FIG. 6 is a sectional view illustrating a structure of a first support roller of Embodiment 1;

FIG. 7 is a schematic perspective view illustrating a schematic configuration of a sheet member conveying apparatus of Embodiment 2;

FIG. 8 is a schematic perspective view illustrating a schematic configuration of a sheet member conveying apparatus of Embodiment 3;

FIG. 9 is a view illustrating a winding angle of a positive-electrode sheet of Embodiment 3;

FIG. 10 is a schematic side view illustrating a schematic configuration of a sheet member conveying apparatus of Embodiment 4;

FIG. 11 is a view illustrating an arrangement of a magnetic-force detection sensor of the sheet member conveying apparatus of Embodiment 4;

FIG. 12 is a schematic side view illustrating a schematic configuration of a sheet member conveying apparatus of Embodiment 5;

FIG. 13 is a schematic side view illustrating a schematic configuration of a sheet member conveying apparatus of Embodiment 6;

FIG. 14 is a schematic side view illustrating a schematic configuration of a sheet member conveying apparatus of Embodiment 7;

FIG. 15 is a view illustrating evaluation results in Example;

FIG. 16 is a view illustrating the results in FIG. 15 in a graph manner; and

FIG. 17 is a view illustrating a range of foreign matters with a magnitude of 0 to 200 μm in FIG. 16 in an enlarged manner.

### DETAILED DESCRIPTION OF EMBODIMENTS

Embodiments of a sheet member inspection method and a sheet member conveying apparatus in the present disclosure will be described with reference to the drawings. In the following embodiments, when a number, an amount, and the like are mentioned, the range of the present disclosure is not necessarily limited to the number, the amount, and the like unless otherwise specified. The same component and its equivalent component has the same reference numeral, and redundant descriptions thereof may not be repeated. Configurations in the embodiments can be used in combination appropriately, which is expected from the beginning. In the drawings, some descriptions are made with different ratios to facilitate understanding of a structure.

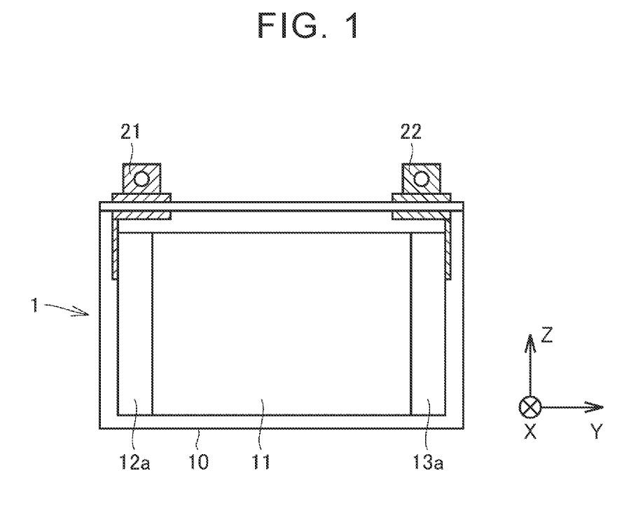

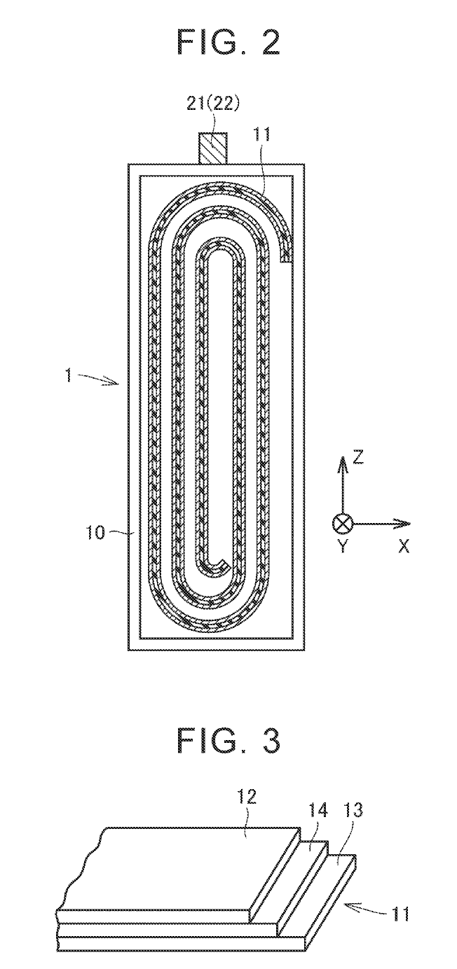

(Structure of Single Cell (Secondary Battery) 1) A configuration of a single cell 1 according to the present embodiment will be described with reference to FIGS. 1 to 3. FIG. 1 is a view illustrating an inner configuration in the single cell according to the present embodiment, FIG. 2 is a sectional view of the single cell 1 taken along a plane X-Z, and FIG. 3 is a schematic perspective view of an electrode sheet. In FIGS. 1 and 2, X, Y and Z-axes indicate three axes perpendicular to each other.

The single cell 1 includes a battery outer case 10, and a power generation element 11 accommodated in the battery outer case 10. As illustrated in FIG. 2, the power generation element 11 is an element that can perform charge and discharge, and is accommodated inside the battery outer case 10 in a wound state.

As illustrated in FIG. 3, the power generation element 11 is constituted by a positive-electrode sheet 12, a negative-electrode sheet 13, and a separator 14 placed between the positive-electrode sheet 12 and the negative-electrode sheet 13. The positive-electrode sheet 12, the negative-electrode sheet 13, and the separator 14 are formed in a sheet shape. Here, the positive-electrode sheet 12 is constituted by a current collector (foil) and a positive electrode layer formed on a surface of the current collector. The positive electrode layer can be formed on either side or both sides of the current collector. The positive electrode layer may include an active material and a conductive agent for a positive electrode.

The negative-electrode sheet 13 is constituted by a current collector and a negative electrode layer formed on a surface of the current collector. The negative electrode layer can be formed on either side or both sides of the current collector. The negative electrode layer may include an active material and a conductive agents for a negative electrode.

It is also possible to use an electrode (a so-called bipolar electrode) configured such that a positive electrode layer is formed on one surface of a current collector, and a negative electrode layer is formed on the other surface of the current collector. Further, an electrolytic solution is used in the present embodiment, but a solid electrolyte formed by particles can also be used. The solid electrolyte may be, for example, polymer solid electrolyte or inorganic solid electrolyte.

In the present embodiment, as illustrated in FIGS. 1 and 2, the single cell 1 is assumed a so-called square-shaped configuration, but is not limited to this, and the single cell 1 can have a so-called cylindrical configuration. That is, the battery outer case 10 may be formed in a cylindrical shape, so that the power generation element 11 can be accommodated inside the battery outer case 10 in a state where the power generation element 11 is wound.

In a case where the single cell 1 is a nickel-metal hydride battery, nickel oxide can be used as the active material for the positive electrode layer, and hydrogen absorbing alloys such as MmNi (5-x-y-z) AlxMnyCoz (Mm: mischmetal) can be used as the active material for the negative electrode layer. In a case where the single cell 1 is a lithium-ion battery, lithium transition metal compound oxide can be used as the active material for the positive electrode layer, and carbon can be used as the active material for the negative electrode layer. Further, acetylene black, carbon black, graphite, carbon fiber, and carbon nanotube can be used as the conductive agent.

Referring now to FIGS. 1 and 2, a positive terminal 21 is electrically and mechanically connected to a positive electrode tab 12a connected to the positive-electrode sheet 12 of the power generation element 11. As illustrated in FIG. 1, the positive electrode tab 12a connected to the positive terminal 21 projects from one end, in a Y-direction, of the power generation element 11 in a wound state. The positive electrode tab 12a can be constituted integrally with or differently from the current collector of the positive-electrode sheet 12.

A negative terminal 22 is electrically and mechanically connected to a negative electrode tab 13a connected to the negative-electrode sheet 13 of the power generation element 11. The negative electrode tab 13a connected to the negative terminal 22 projects from the other end, in the Y-direction, of the power generation element 11 in a wound state. The negative electrode tab 13a can be constituted integrally with or differently from the current collector of the negative-electrode sheet 13.

The positive terminal 21 and the negative terminal 22 project from a top face of the battery outer case 10, and are electrically connected to an electronic device (not shown) via a wiring line (not shown). Hereby the electronic device can be driven by use of an output of the single cell 1.

In a case where the single cell 1 is used as a drive source of a vehicle, a plurality of single cells 1 is prepared and the single cells 1 are electrically connected in series, so that a battery module can be formed. Energy necessary for vehicle running is taken out from the battery module. The positive terminal 21 and the negative terminal 22 in each of the single cells 1 are electrically connected to the positive terminal 21 and the negative terminal 22 in another single cell 1 via a bus bar. Examples of a vehicle including the battery module includes a hybrid vehicle in which the battery module is used together with another power source such as an internal combustion engine or a fuel cell, and an electric vehicle including only the battery module as a power source.

A manufacturing method of a secondary battery according to the present embodiment has a feature in a sheet member inspection method for inspecting whether or not a magnetic object (hereinafter referred to as a foreign matter) is included in a sheet member (the positive-electrode sheet 12, the negative-electrode sheet 13, the separator 14) of a power generation element wound as a wound body, and a sheet member conveying apparatus executing the inspection method. The following description mainly deals with the sheet member inspection method and the sheet member conveying apparatus executing the inspection method. When inspecting, a sheet member determined to have a magnetic foreign matter is discarded, and a sheet member determined not to have a magnetic foreign matter is used as a wound body. By specifying an element of the magnetic foreign matter included in the sheet member to be discarded, a route of contamination of the magnetic foreign material is specified, which can be used as improvement information for a manufacturing process.

In each of the following embodiments, a case where the positive-electrode sheet 12 is used as a sheet member will be explained, but the negative-electrode sheet 13, the separator 14, and the power generation element 11 may be used as the sheet member.

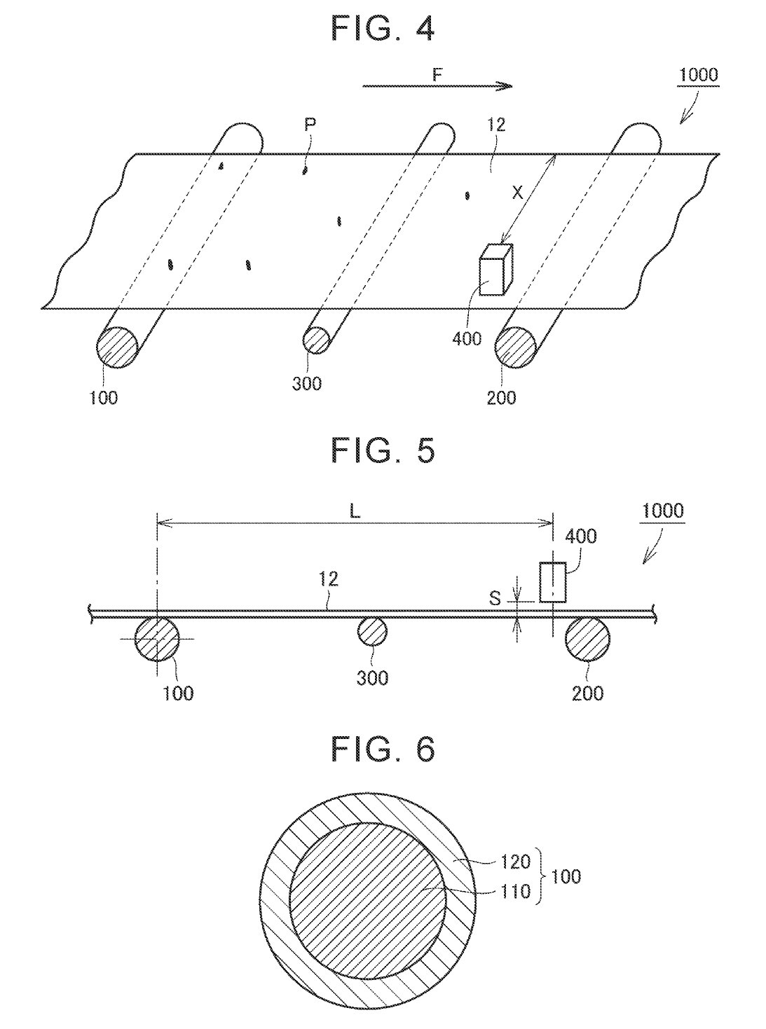

(Embodiment 1) With reference to FIGS. 4 to 6, the following describes a sheet member inspection method in the present embodiment and a sheet member conveying apparatus 1000 executing the inspection method. FIGS. 4 and 5 are a schematic perspective view and a schematic side view illustrating a schematic configuration of the sheet member conveying apparatus 1000, and FIG. 6 is a sectional view illustrating a structure of a first support roller 100.

With reference to FIG. 4, the sheet member conveying apparatus 1000 employs the sheet member inspection method for conveying a positive-electrode sheet 12 with a tension and detecting a magnetic foreign matter mixed in the positive-electrode sheet 12. The sheet member conveying apparatus 1000 is configured such that the first support roller 100 that supports conveyance of the positive-electrode sheet 12 is placed on an upstream side in a conveying direction (an arrow-F direction in FIG. 4) of the positive-electrode sheet 12.

A second support roller 200 that supports the conveyance of the positive-electrode sheet 12 is placed on a downstream side relative to the first support roller 100 in the conveying direction. In the present embodiment, an auxiliary support roller 300 is placed between the first support roller 100 and the second support roller 200. In the present embodiment, the positive-electrode sheet 12 is conveyed along a generally horizontal plane.

The first support roller 100 is magnetized. In a case where a foreign matter P is mixed in the positive-electrode sheet 12, the foreign matter P is magnetized by the first support roller 100. A magnetic force is preferably 200 mT or more. As a size of the foreign matter P, it is assumed that a maximum length is 300 μm or less.

A magnetic-force detection sensor 400 for detecting a magnetic force is placed on the downstream side relative to the first support roller 100 in the conveying direction. The magnetic-force detection sensor 400 is placed in the vicinity of the second support roller 200, and is configured to reciprocate (scan in a reciprocating manner) in a direction (an arrow-X direction in the figure) where a rotating shaft of the second support roller 200 extends, so as to inspect a magnetic foreign matter included in the positive-electrode sheet 12.

That is, the sheet member inspection method in the present embodiment includes a step of applying a magnetic force to the positive-electrode sheet 12 by the first support roller 100, and a step of inspecting, by the magnetic-force detection sensor 400, whether or not a magnetized foreign matter exists in the positive-electrode sheet 12 to which the magnetic force is applied by the first support roller 100.

As illustrated in FIG. 5, in order that the magnetic-force detection sensor 400 is not affected by the magnetic force of the first support roller 100, it is preferable that an arrangement position (a distance L in the figure) of the magnetic-force detection sensor 400 be distanced from a rotation center position of the first support roller 100 by about 200 mm or more. It is preferable that a distance (a distance S in the figure) from a surface of the positive-electrode sheet 12 to the magnetic-force detection sensor 400 be about 0.1 mm to 0.5 mm.

As illustrated in FIG. 6, the first support roller 100 is configured such that a magnet layer 120 is provided on a surface of a core 110 made of metal or the like, for example, so that the foreign matter P mixed in the positive-electrode sheet 12 can be magnetized.

In the sheet member conveying apparatus 1000 having the above configuration, the first support roller 100 is magnetized, and in a case where the foreign matter P is mixed in the positive-electrode sheet 12, the foreign matter P is magnetized by the first support roller 100, so that the magnetic-force detection sensor 400 can detect the foreign matter thus magnetized. That is, the sheet member conveying apparatus 1000 can execute the sheet member inspection method as described above.

As such, in the sheet member inspection method and the sheet member conveying apparatus 1000 executing the inspection method, the conveyance of the positive-electrode sheet 12 is supported by the first support roller 100 that is magnetized. As a result, in a case where the foreign matter P is mixed in the positive-electrode sheet 12, the foreign matter P is surely magnetized because the positive-electrode sheet 12 is conveyed in a state where the positive-electrode sheet 12 makes contact with the first support roller 100. Hereby, the magnetic-force detection sensor 400 can surely detect the magnetized foreign matter P from the positive-electrode sheet 12.

Further, since the foreign matter P is surely magnetized, it is not necessary to place the magnetic-force detection sensor 400 closer to the positive-electrode sheet 12 needlessly, which makes it possible to restrain such a situation that, when the positive-electrode sheet 12 moves in an up-down direction, the magnetic-force detection sensor 400 makes contact with the positive-electrode sheet 12 to damage the positive-electrode sheet 12.

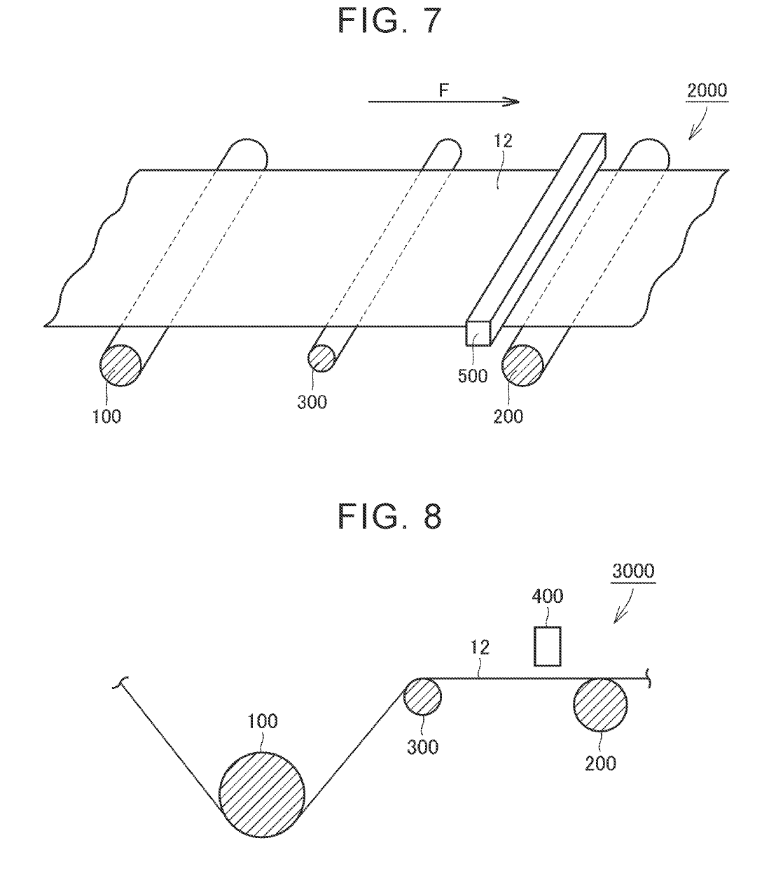

(Embodiment 2) Referring to FIG. 7, the following describes a sheet member inspection method in the present embodiment and a sheet member conveying apparatus 2000 executing the inspection method. FIG. 7 is a schematic perspective view illustrating a schematic configuration of the sheet member conveying apparatus 2000.

A basic configuration is the same as the sheet member conveying apparatus 1000 in Embodiment 1. A difference is that a magnetic-force detection sensor 500 is provided instead of the magnetic-force detection sensor 400. The magnetic-force detection sensor 400 is a scanning sensor, but the present embodiment uses a sensor that can detect an overall width of a positive-electrode sheet 12 in a width direction (a direction where a rotating shaft of a second support roller 200 extends) at a time. The magnetic-force detection sensor 500 is configured such that a plurality of magnetic-force detection sensors is arranged in the width direction of the positive-electrode sheet 12 so as not cause a detection leakage range.

In terms of the magnetic-force detection sensor 400 of Embodiment 1, it is presumable that an upper limit of a conveyance speed of the positive-electrode sheet 12 is determined by a scanning speed. However, in a case of using the magnetic-force detection sensor 500, it is possible to increase the conveyance speed of the positive-electrode sheet 12.

With the use of the sheet member inspection method of the present embodiment and the sheet member conveying apparatus 2000 executing the inspection method, it is possible to obtain an effect similar to Embodiment 1 and to increase the conveyance speed of the positive-electrode sheet 12, as described above.

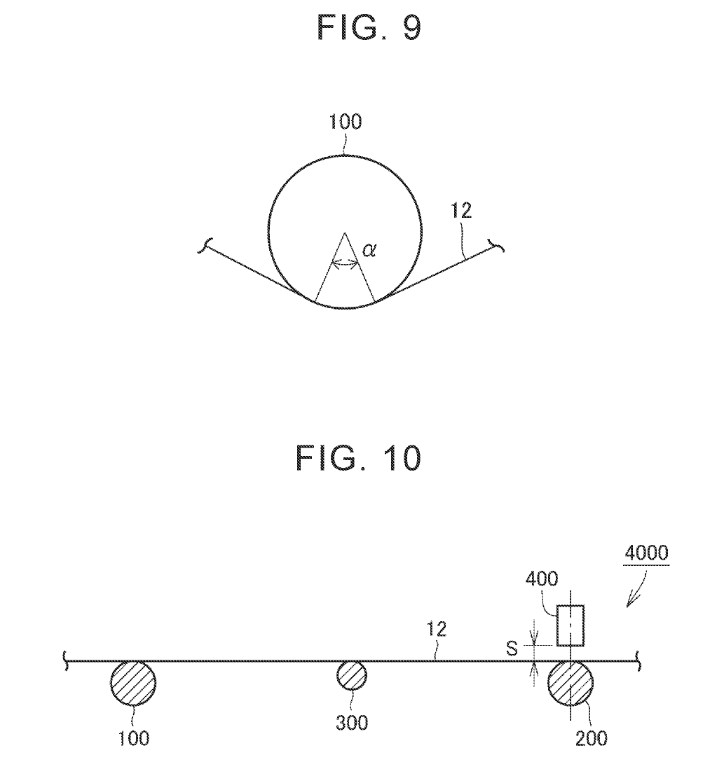

(Embodiment 3) Referring to FIGS. 8 and 9, the following describes a sheet member inspection method in the present embodiment and a sheet member conveying apparatus 3000 executing the inspection method. FIG. 8 is a schematic perspective view illustrating a schematic configuration of the sheet member conveying apparatus 3000, and FIG. 9 is a view illustrating a winding angle of a positive-electrode sheet 12.

A basic configuration is the same as the sheet member conveying apparatus 1000 in Embodiment 1. A difference is an arrangement position of a first support roller 100. In the present embodiment, a position of a second support roller 200 is placed on an upper side relative to a position of the first support roller 100, and a positive-electrode sheet 12 is supported so as to pass through an upper side of the second support roller 200 after passing through a lower side of the first support roller 100.

As illustrated in FIG. 9, in a case where the positive-electrode sheet 12 passes through the lower side of the first support roller 100, it is preferable that a winding angle a of the positive-electrode sheet 12 with respect to the first support roller 100 be from around 10 to 45 degrees.

When the positive-electrode sheet 12 passes through the upper side of the second support roller 200 after passing through the lower side of the first support roller 100 as such, it is possible to prevent an occurrence of looseness of the positive-electrode sheet 12 at the time of the conveyance. This consequently restrains the movement of the positive-electrode sheet 12 in the up-down direction, thereby making it possible to restrain the magnetic-force detection sensor 400 from making contact with the positive-electrode sheet 12 and damaging the positive-electrode sheet 12.

With the use of the sheet member inspection method of the present embodiment and the sheet member conveying apparatus 3000 executing the inspection method, it is possible to obtain an effect similar to Embodiment 1 and to restrain the movement of the positive-electrode sheet 12 in the up-down direction, as described above.

(Embodiment 4) Referring to FIGS. 10 and 11, the following describes a sheet member inspection method in the present embodiment and a sheet member conveying apparatus 4000 executing the inspection method. FIG. 10 is a schematic perspective view illustrating a schematic configuration of the sheet member conveying apparatus 4000, and FIG. 11 is a view illustrating the sheet member inspection method in Embodiment 4 and a magnetic-force detection sensor of the sheet member conveying apparatus.

A basic configuration is the same as the sheet member conveying apparatus 1000 in Embodiment 1. A difference is an arrangement position of a magnetic-force detection sensor 400. In the sheet member conveying apparatus 4000 of the present embodiment, the magnetic-force detection sensor 400 is placed above a second support roller 200. Here, with reference to FIG. 11, that the magnetic-force detection sensor 400 is placed above the second support roller 200 indicates that a sensor center SCL of the magnetic-force detection sensor 400 is positioned within a range of a diameter D of the second support roller 200.

In a state where the positive-electrode sheet 12 makes contact with the second support roller 200, the positive-electrode sheet 12 hardly moves in the up-down direction. In view of this, the magnetic-force detection sensor 400 is placed above a region where the positive-electrode sheet 12 makes contact with the second support roller 200, thereby making it possible to restrain the magnetic-force detection sensor 400 from making contact with the positive-electrode sheet 12 and damaging the positive-electrode sheet 12.

With the use of the sheet member inspection method of the present embodiment and the sheet member conveying apparatus 4000 executing the inspection method, it is possible to obtain an effect similar to Embodiment 1 and to restrain the movement of the positive-electrode sheet 12 in the up-down direction, as described above.

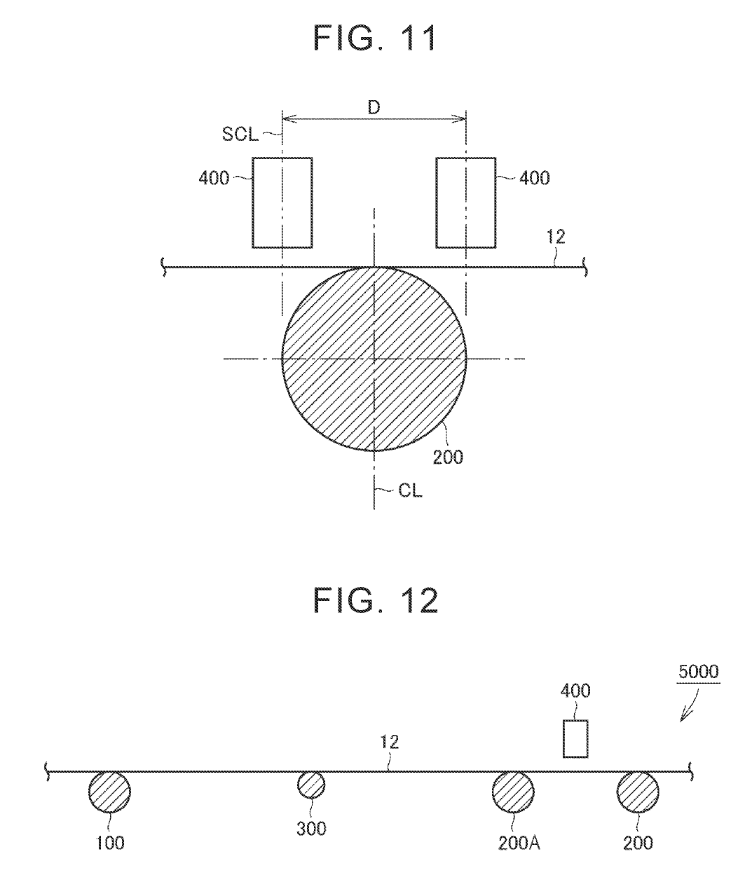

(Embodiment 5) Referring to FIG. 12, the following describes a sheet member inspection method in the present embodiment and a sheet member conveying apparatus 5000 executing the inspection method. FIG. 12 is a schematic side view illustrating a schematic configuration of the sheet member conveying apparatus 5000.

A basic configuration is the same as the sheet member conveying apparatus 1000 in Embodiment 1. A difference is that a third support roller 200A that supports conveyance of a positive-electrode sheet 12 is placed further on the upstream side relative to a second support roller 200 in the conveying direction. A distance between the second support roller 200 and the third support roller 200A is set shorter than a distance between the first support roller 100 and the second support roller 200. The magnetic-force detection sensor 400 is provided above the positive-electrode sheet 12 between the second support roller 200 and the third support roller 200A.

Since the distance between the second support roller 200 and the third support roller 200A is shorter than the distance between the first support roller 100 and the second support roller 200, an up-and-down motion to occur in the positive-electrode sheet 12 between the second support roller 200 and the third support roller 200A can be reduced as compared to the up-and-down motion occurred between the first support roller 100 and the second support roller 200. As a result, when the magnetic-force detection sensor 400 is placed between the second support roller 200 and the third support roller 200A, it is possible to restrain the magnetic-force detection sensor 400 from damaging the positive-electrode sheet 12.

With the use of the sheet member inspection method of the present embodiment and the sheet member conveying apparatus 5000 executing the inspection method, it is possible to obtain an effect similar to Embodiment 1 and to restrain the movement of the positive-electrode sheet 12 in the up-down direction, as described above.

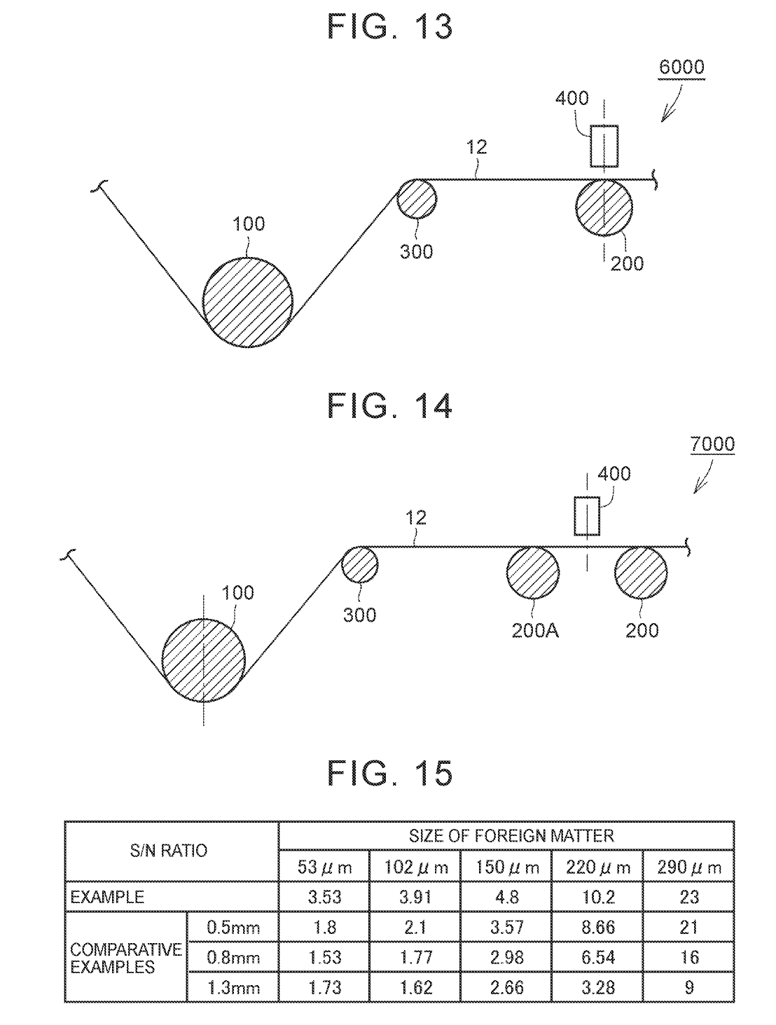

(Embodiment 6) Referring to FIG. 13, the following describes a sheet member inspection method in the present embodiment and a sheet member conveying apparatus 6000 executing the inspection method. FIG. 13 is a schematic side view illustrating a schematic configuration of the sheet member conveying apparatus 6000.

The sheet member conveying apparatus 6000 employs, in combination, a conveyance path of the positive-electrode sheet 12 in the sheet member conveying apparatus 3000 illustrated in Embodiment 3 and an arrangement position of the magnetic-force detection sensor 400 of the sheet member conveying apparatus 4000 illustrated in Embodiment 4.

With the use of the sheet member conveying apparatus 6000, the effects of Embodiments 3 and 4 can be obtained at the same time.

(Embodiment 7) Referring to FIG. 14, the following describes a sheet member inspection method in the present embodiment and a sheet member conveying apparatus 7000 executing the inspection method. FIG. 14 is a schematic side view illustrating a schematic configuration of the sheet member conveying apparatus 7000.

The sheet member conveying apparatus 7000 employs, in combination, the conveyance path of the positive-electrode sheet 12 in the sheet member conveying apparatus 3000 illustrated in Embodiment 3 and an arrangement position of the third support roller 200A and the magnetic-force detection sensor 400 of the sheet member conveying apparatus 5000 illustrated in Embodiment 5.

With the use of the sheet member conveying apparatus 7000, the effects of Embodiments 3 and 5 can be obtained at the same time.

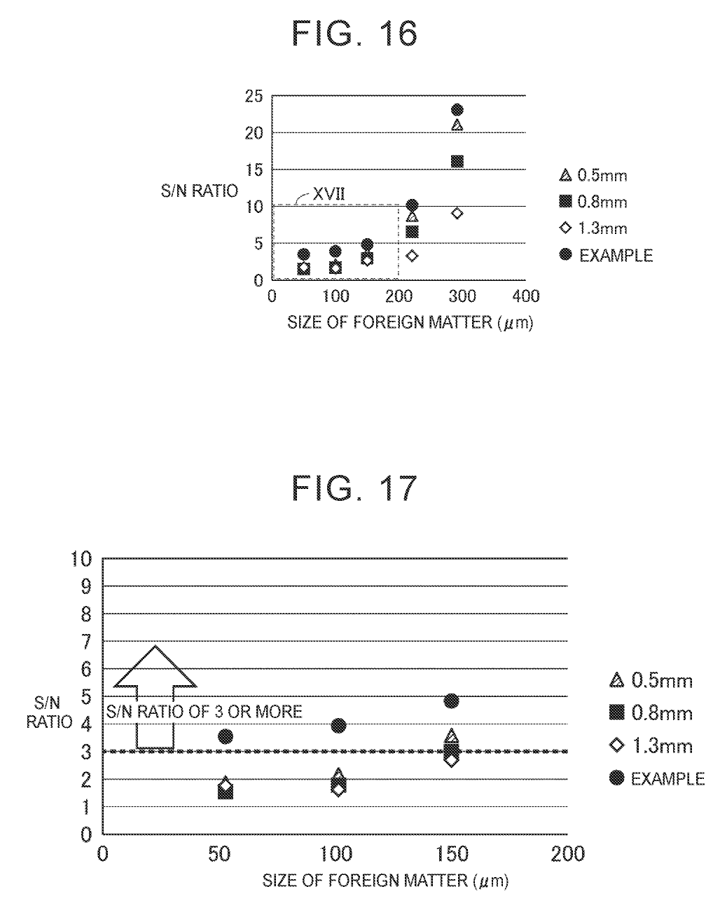

(Example) Example will now be described with reference to FIGS. 15 to 17. FIG. 15 is a view illustrating evaluation results in Example, FIG. 16 is a view illustrating the results in FIG. 15 in a graph manner, and FIG. 17 is a view illustrating a range of foreign matters with a magnitude of 0 to 200 μm in FIG. 16 in an enlarged manner.

The present example is based on a result using the sheet member conveying apparatus 3000 illustrated in Embodiment 3 with reference to FIG. 8. An aluminum foil of 12 μm was used as the positive-electrode sheet 12. As the magnet layer 120 of the first support roller 100, a magnet having a magnetic force of 200 mT was used. A conveyance speed of the positive-electrode sheet 12 is 5 m/min. As the foreign matter P, Fe-grains were used. A distance between the magnetic-force detection sensor 400 and the positive-electrode sheet 12 was 0.4 mm.

As a size of the foreign matter P, five types of 53 μm, 102 μm, 150 μm, 220 μm, and 290 μm were used. As Comparative Examples, a first support roller 100 having no magnetic force was used, and the foreign matters P were magnetized by placing magnets having a magnetic force of 200 mT at respective positions (distance S) away from the positive-electrode sheet 12 by 0.5 mm, 0.8 mm, and 1.3 mm.

The results are shown in FIGS. 15 to 17. Values shown in FIG. 15 indicate magnitudes of signals (S/N ratios) obtained by the magnetic-force detection sensor 400, and in a case where a signal has a value of 3 or more, the signal is processed as a signal indicating that the foreign matter P exists.

In Example, signals with a magnitude of 3 or more were obtained with respect to the foreign matters P of all sizes. In the meantime, in Comparative Examples in which the foreign matters P were magnetized such that the magnets having a magnetic force of 200 mT were placed at respective positions (distance S) away from the positive-electrode sheet 12 by 0.5 mm, 0.8 mm, and 1.3 mm, when the size of the foreign matter was 150 μm or less, a value of a signal was 3 or less in some cases, which made it difficult to detect the foreign matter P.

As such, in the embodiments, the conveyance of the positive-electrode sheet 12 is supported by the first support roller 100 that is magnetized. As a result, in a case where the foreign matter P is mixed in the positive-electrode sheet 12, the foreign matter P is surely magnetized because the positive-electrode sheet 12 is conveyed in a state where the positive-electrode sheet 12 makes contact with the first support roller 100. Hereby, the magnetic-force detection sensor 400 can surely detect the magnetized foreign matter P from the positive-electrode sheet 12.

Further, since the foreign matter P is surely magnetized, it is not necessary to bring the magnetic-force detection sensor 400 closer to the positive-electrode sheet 12 needlessly, which makes it possible to restrain such a situation that, when the positive-electrode sheet 12 moves in the up-down direction, the magnetic-force detection sensor 400 makes contact with the positive-electrode sheet 12 to damage the positive-electrode sheet 12.

The embodiments exemplify a case where a laminated battery is a nickel-metal hydride battery, but the present disclosure is not limited to this, and the laminated battery may be a lithium-ion battery, a nickel zinc battery, a nickel cadmium battery, and the like. Note that in the case of a lithium-ion battery, a nickel zinc battery, or a nickel cadmium battery, members constituting a positive-electrode sheet, a negative-electrode sheet, a separator, and an electrolytic solution can be selected appropriately depending on the type of the battery.

The embodiments have been described above, but the embodiments described herein are just examples in all respects and are not limitative. A technical scope of the present disclosure is shown by Claims, and intended to include all modifications made within the meaning and scope equivalent to Claims.

The sheet member inspection method described and the sheet member conveying apparatus described in the present specification are used for manufacture of an electrode sheet for a secondary battery used in a laminated battery to be applied to a vehicle and various devices, for example.

What is claimed is:

1. A sheet member inspection method for a sheet member conveying apparatus configured to convey a sheet member with a tension so as to detect a magnetic object mixed in the sheet member, the sheet member conveying apparatus including a first support roller placed on an upstream side in a conveying direction of the sheet member and configured to support conveyance of the sheet member, a second support roller placed on a downstream side relative to the first support roller in the conveying direction and configured to support the conveyance of the sheet member, and a magnetic-force detection sensor placed on the downstream side relative to the first support roller in the conveying direction and configured to detect a magnetic force, the first support roller being magnetized, the sheet member inspection method comprising:
applying a magnetic force to the sheet member by the first support roller; and
inspecting, by the magnetic-force detection sensor, whether or not the object that is magnetized exists in the sheet member to which the magnetic force is applied by the first support roller.

2. The sheet member inspection method according to claim 1, wherein
the magnetic-force detection sensor is placed above the second support roller.

3. The sheet member inspection method according to claim 1, wherein
a position of the second support roller is placed on an upper side relative to a position of the first support roller; and
the sheet member is supported so as to pass through an upper side of the second support roller after passing through a lower side of the first support roller.

4. The sheet member inspection method according to claim 1, wherein the sheet member is any one of an electrode sheet, a positive-electrode sheet, a separator, and a negative-electrode sheet.

5. A sheet member conveying apparatus configured to convey a sheet member with a tension so as to detect a magnetic object mixed in the sheet member, the sheet member conveying apparatus comprising:
a first support roller placed on an upstream side in a conveying direction of the sheet member and configured to support conveyance of the sheet member;
a second support roller placed on a downstream side relative to the first support roller in the conveying direction and configured to support the conveyance of the sheet member; and
a magnetic-force detection sensor placed on the downstream side relative to the first support roller in the conveying direction and configured to detect a magnetic force, wherein
the first support roller is magnetized.
